(19) United States
(12) Patent Application Publication
(10) Pub. No.: US 2010/0330830 A1
(43) Pub. Date: Dec. 30, 2010

(54) Vertical probe intrface system

(75) Inventor: Ka Ng Chui, (US)

Correspondence Address: Corad Technology Inc.;Suite 202B, 3080 Olcott Street, Santa Clara, CA, 95054, US

(73) Assignee: Corad Technology Inc., Santa Clara, CA (US)

(21) Appl. No.: 12/457,924

(22) Filed: Jun. 25, 2009

(51) Int. Cl. H01R 29/00; H05K 1/00

(52) U.S. Cl. 439/169; 174/254

(57) ABSTRACT

A vertical probe interface system includes a flex PCB system where a portion of the flex PCB is pressed together to form a solid board and the other portion of the flex PCB is in layer or layers form. A metal plate mounts the flex PCB to the stiffener of the probe interface board. The flex PCB is electrically connected to the probe interface board by connectors, soldering or other known method.

### BACKGROUND OF THE INVENTION

The present invention relates to integrated circuit technology. More particularly, the present invention relates to a test method and test apparatus for integrated circuitry technology.

Vertical probes are used in testing ICs at wafer level, and recently the package level. The test set up typically includes vertical probes, vertical probe head, a space transformer, a probe card, a pogo tower and a probe interface board. The space transformer is to space out the pitch of the probes for connection to the probe card. The pogo tower provides connection between the probe card and the probe interface board, which is connected to an automatic testing equipment (ATE) machine.

New interface system is required to simply the set up for both signal performance and cost improvement.

### BRIEF SUMMARY OF THE INVENTION

The present invention provides a new interface for integrated circuitry technology. More particularly, the present invention provides an interface system between the vertical probe head and the probe interface board.

According to one embodiment of the present invention, an interface system provides direct connection between the vertical probe head and the probe interface board. The vertical probe interface system serves the functions of the space transformer, the probe card and the pogo tower. The vertical probe interface system consists of a plurality of layers of flex PCB. The plurality layers of flex PCB is pressed together to form one solid board corresponding to the vertical probe head area, and the plurality of layer or layers of flex PCB are in separate layer or layers outside the vertical probe head area. The vertical probe head is mounted on the first side of the solid board by screw or other mechanical method. A metal plate is mounted on the second side of the solid board, wherein the second side is opposite to the first side. The metal plate is mounted on the probe interface board or to the stiffener of the probe interface board. The layer or layers of flex PCB of the probe head interface system are connected to the probe interface board outside the probe head area.

According to a specific embodiment of the vertical probe interface system, the flex PCB has a plurality of traces and a plurality of pads wherein the pads are on a first side of the flex PCB. The plurality of pads are substantially aligned with the vertical probes of the probe head. The plurality of pads and traces on the probe head interface system provide electrical connection between the vertical probes and the probe interface board.

According to a specific embodiment of the vertical probe interface system, the plurality of layer or layers of flex PCB are connected to male (female) connectors and the male (female) connectors are docked to the female (male) connectors on the probe interface board. This provides direct electrical connection between the flex PCB and the probe interface board. The pogo tower is no longer required. The height of the metal plate is designed in such way that the system will work with the same setup after the pogo tower is removed from the system. The layer or layers of flex PCB can be connected to the wafer interface board by soldering or by other known method.

According to a specific embodiment of the vertical probe interface system, the metal plate mounted on the second side of the solid board is mounted on the stiffener of the probe interface board and provides support for the force of the vertical probes. The force is transmitted from the vertical probes to the probe interface board stiffener. This configuration prevents bending of the probe interface board and bending of the wafer probe machine.

### BRIEF DESCRIPTION OF THE DRAWINGS

FIG. 1 is the current vertical probe interface set up.

FIG. 2A is simplified cross-sectional view of a vertical probe interface system according to one embodiment of the present invention.

FIG. 2B is simplified cross-sectional view of a vertical probe interface system according to another embodiment of the present invention.

FIG. 3 is simplified bottom view of the flex PCB of the present invention.

### DETAILED DESCRIPTION OF THE INVENTION

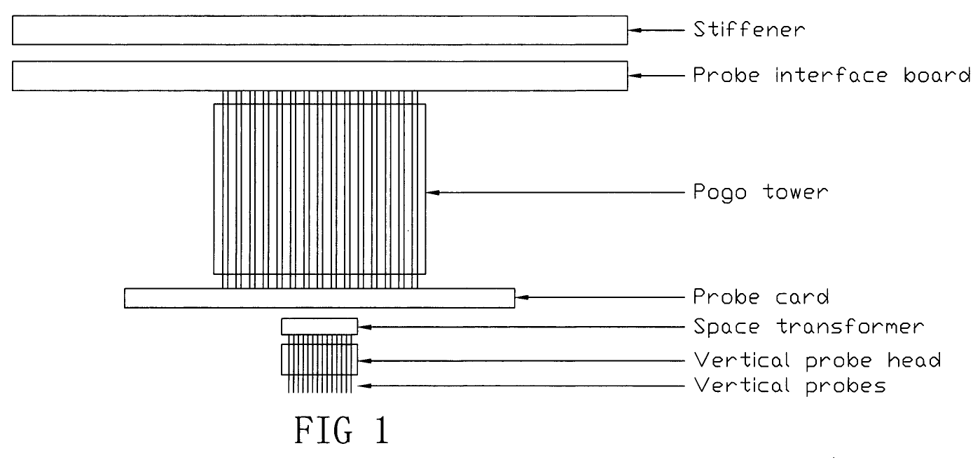

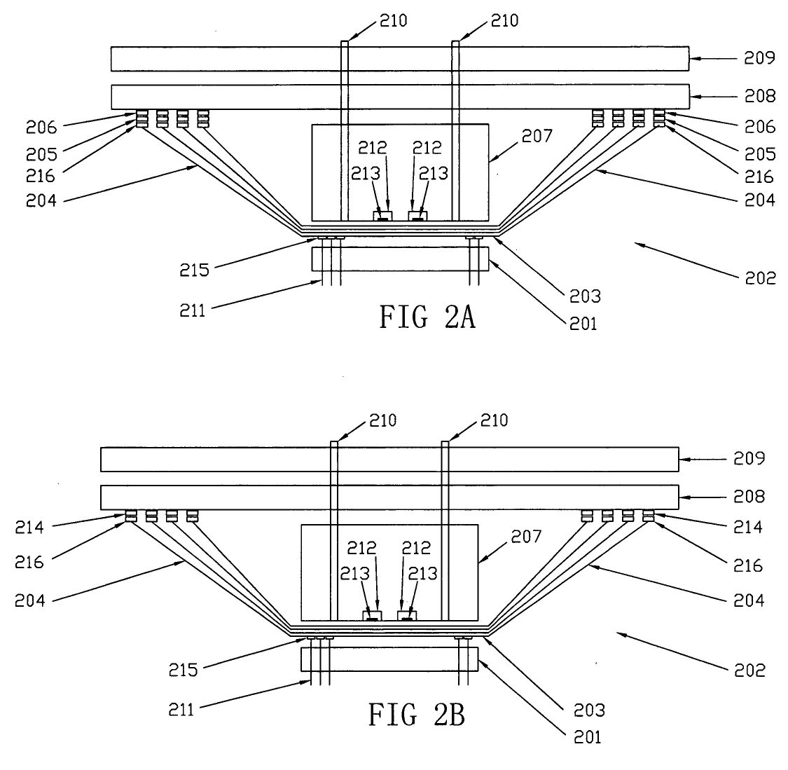

FIG. 2A is simplified cross-sectional view of the vertical probe interface system according to one embodiment of the present invention. 201 is the vertical probe head. 202 is the flex PCB. At location of the vertical probe head 201, it is pressed together to form a solid board 203. A plurality of pads 215 are on the first side of the board 203 and are substantially aligned with vertical probes 211. Outside the vertical probe head 201, the flex PCB are in separate layer or layers 204. Pads 216 of each layer of flex PCB 204 is connected to a male connector 205. Female connectors 206 are installed on the probe interface board 208. Male connector 205 is mounted to the female connector 206. 209 is the stiffener for probe interface board 208. A metal plate 207 is mounted to the stiffener 209 as shown in position 210. Flex PCB board 203 is mounted to the metal plate 207. The height of the metal plate 207 is designed in such way that the total height from the tips of the vertical probes 211 to the bottom of the probe interface board 208 is the same as that of the current probe interface set up in FIG. 1.

FIG. 2B is simplified cross-sectional view of the vertical probe interface system according to another embodiment of the present invention. 201 is the vertical probe head. 202 is the flex PCB. At location of the vertical probe head 201, it is pressed together to form a solid board 203. A plurality of pads 215 are on the first side of the board 203 and are substantially aligned with vertical probes 211. Outside the vertical probe head 201, the flex PCB are in separate layer or layers 204. Pads 216 on each layer of flex PCB 204 is connected to corresponding pads 214 on probe interface board 208 by soldering or other known method. 209 is the stiffener for probe interface board 208. A metal plate 207 is mounted to the stiffener 209 as shown in position 210. Flex PCB board 203 is mounted to the metal plate 207. The height of the metal plate 207 is designed in such way that the total height from the tips of the vertical probes 211 to the bottom of the probe interface board 208 is the same as that of the current probe interface set up in FIG. 1.

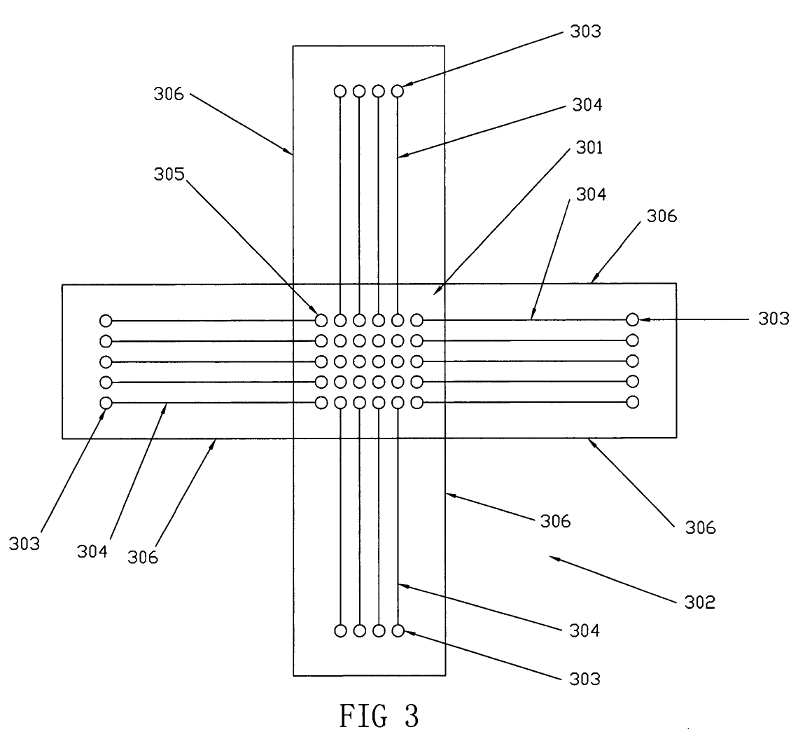

FIG. 3 is the bottom view of the flex PCB 302. 305 are a plurality of pads substantially aligned to the probes of the vertical probe head. 304 are a plurality of traces connecting pads 305 to pads 303 near the outside of the flex PCB 302. 301 is the location of the flex PCB corresponding to the probe head location and is pressed together to form a board. The shape of 301 can be square, round or other shapes to correspond with the shape of the vertical probe head. 306 is the location of the flex PCB outside the vertical probe head. 306 is in separate layer form. Each layer has traces 304 connecting pads 305 to pads 303. The shape of 306 can be in different form to take advantage of the available space.

On FIG. 3, power pads and ground pads of 305 can be connected by via from the first side (vertical probe head side) to the second side of the flex PCB board. On both FIGS. 2A and 2B, cavity 212 is generated on the metal plate 207. Decoupling capacitor 213 is installed inside the cavity for the power pads of the flex PCB board and they provide very close decoupling for the vertical power probe.

What is claimed is:

1. A vertical probe interface system comprises:
a flex PCB with one area pressed together to form a board and the other area is in separate layer or layers form.

2. The vertical probe interface system of claim 1, further comprising:
a plurality of pads on the first side and at the pressed board area with positions substantially aligned to the probes of the vertical probe head. The pads at the pressed board area is connected by trace on different layers of the flex PCB to the pads near the outside of the flex PCB.

3. The traces of claim 2 can be with impedance control with trace and ground layup configuration.

4. The pads near the outside of the flex PCB of claim 2 can be connected to the probe interface board by connectors, soldering or other known method.

5. The vertical probe interface system of claim 1 further comprising:
a metal plate mounted on the stiffener of the probe interface board. The flex PCB is mounted on the metal plate. The height of the metal plate is designed to allow the system height from the tips of the vertical probes to the bottom of the probe interface board the same as the original set up of the probe system, which comprises of vertical probes, a vertical probe head, a space transformer, a probe card, and a pogo tower.

6. The metal plate mounted on the stiffener of the probe interface board transfers the force from the vertical pogo pins to the stiffener and prevents bending of the probe interface board and bending of the wafer prober.

7. Cavity is generated on the metal plate of claim 5 to allow decoupling capacitor be installed at the second side (back side) of the flex PCB to be very close to the power probes.
